(19) United States
(12) Patent Application Publication
(10) Pub. No.: US 2006/0261406 A1
(43) Pub. Date: Nov. 23, 2006

(54) Vertical integrated-gate CMOS device and its fabrication process

(76) Inventor: Yijian Chen, Albany, CA (US)

Correspondence Address: Yijian Chen, 1049 Talbot Avenue, Albany, CA, 94706, US

(21) Appl. No.: 11/130,564

(22) Filed: May 18, 2005

(51) Int. Cl. H01L 21/336; H01L 31/00

(52) U.S. Cl. 257/329; 438/268; 257/E21.41

(57) ABSTRACT

A vertical integrated-gate CMOS (Complementary Metal-Oxide-Silicon field effect transistor) device is invented for the first time and its possible fabrication processes are proposed. This CMOS architecture integrates PMOS (P-channel MOSFET) and NMOS (N-channel MOSFET) together vertically to increase the transistor density, and use epitaxy layer thickness to define the transistor channel/gate length. The epitaxy growth rate can be controlled accurately thus with much less channel/gate critical dimension (CD) variations than defined by lithography, which also relaxes lithographic resolution requirements for continuous cost-effective CMOS shrinking. This device structure can be used in the post-planar-CMOS ultra-dense integrated circuits.

A vertical integrated-gate CMOS (Complementary Metal-Oxide-Silicon field effect transistor) device is invented and some examples of its fabrication process are shown. This novel CMOS architecture integrates multiple-gate (double-gate and surrounding-gate) PMOS and NMOS together vertically to increase the transistor density, and use epitaxy-Si (or SiGe, Ge) to define the channel/gate length with much less critical dimension (CD) variations and relaxed lithographic resolution requirement.

The semiconductor industry is entering a critical stage where conventional-CMOS based electronics and patterning technologies appear to approach their limits with increasing difficulties in sustaining functional device scaling [1]. One challenge comes from the difficulty of using conventional planar single-gate MOSFET; thus multiple-gate structures to control the leakage current need to be adopted [2]. The other challenge relates to the lithography aspect as the resolution enhancement techniques (RET) caused soaring lithographic cost and lithography-defined gate critical dimension variations are serious issues of IC manufacturing. Moreover, in conventional IC design, the NMOS and PMOS of a CMOS unit occupy separate space, which limits our capability to further increase the transistor density. I develop a novel vertical integrated-gate CMOS (VIG CMOS) inverter technology, which combines the advantages of (1) integration of PMOS and NMOS together to significantly increase the transistor density, (2) epitaxy-Si (or SiGe, Ge) growth defined channel/gate length with much less CD variations, (3) multiple-gate control, and (4) relaxed lithographic resolution requirement.

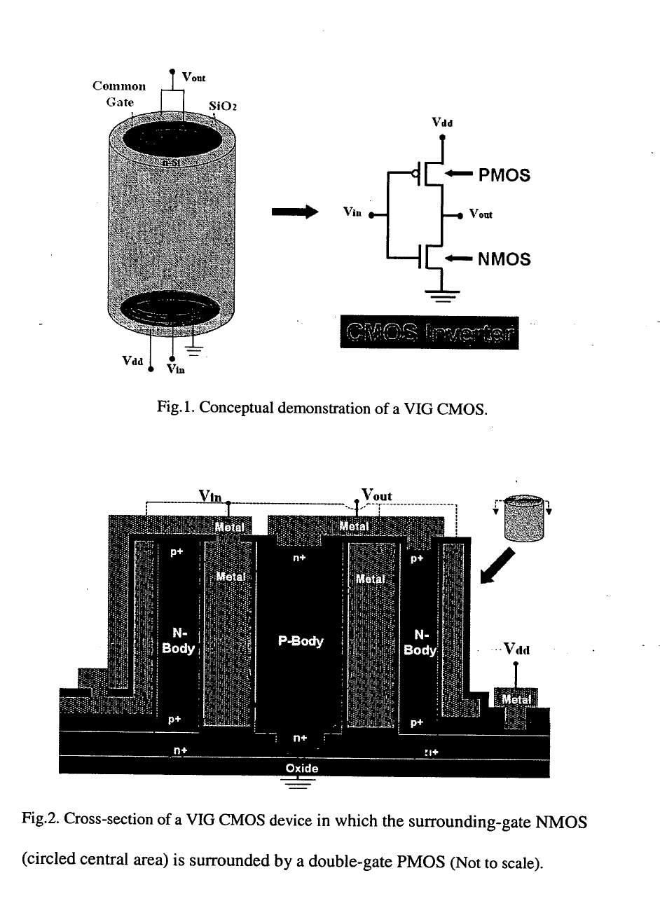

FIG. 1 is a conceptual demonstration of a VIG CMOS inverter, in which PMOS and NMOS, as well as their drain and source, are designed vertically. Their gates are integrated into a narrow trench and the metal contact to this trench area is located on top of the device (see FIG. 2), thus without consuming extra space. The vertical channel/gate length is defined by the epitaxy-Si thickness while the channel/gate width is defined by the Si shell/core circumference epitaxy-Si thickness can be accurately controlled in the growth process with much less gate CD variation than defined by lithography. FIG. 2 is the cross-section view (as indicated by the arrow on the right top) of a practical VIG CMOS structure, in which the surrounding-gate NMOS (circled central area) is surrounded by a double-gate PMOS.

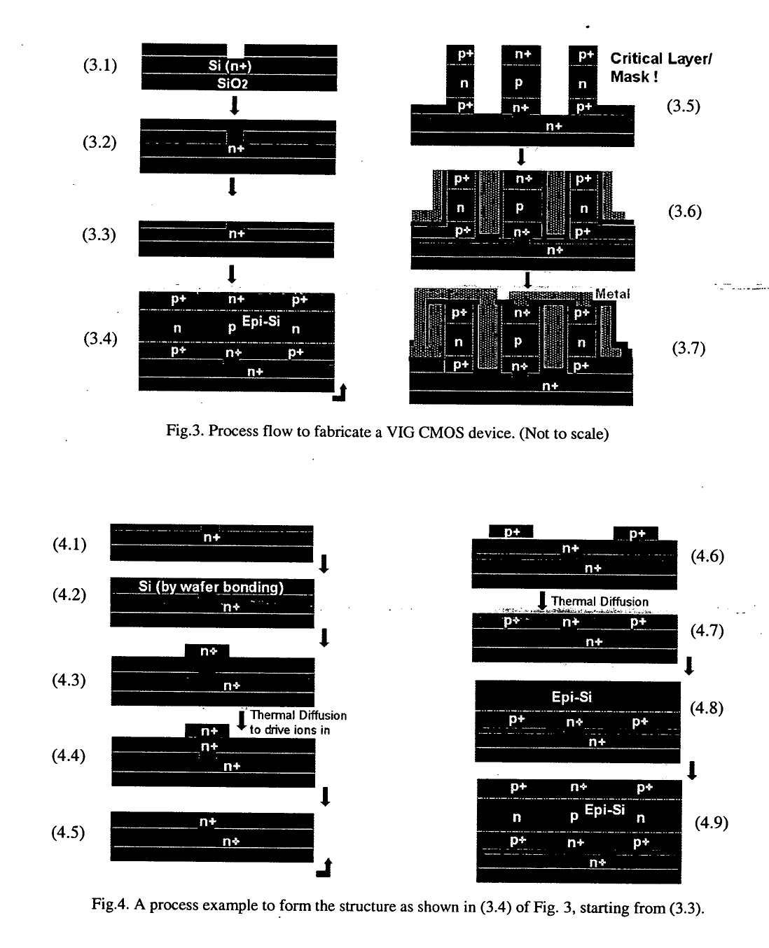

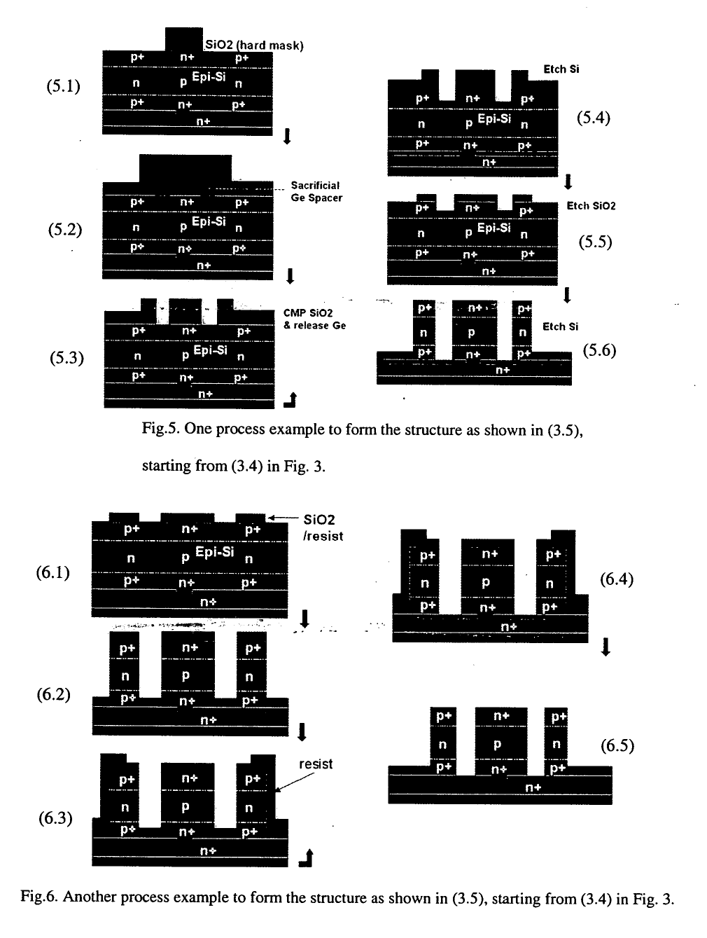

The process flow to fabricate a VIG CMOS is demonstrated in FIG. 3. A brief description of this process flow is given here first, and more detailed information will be shown later. First, we etch a contact to the n+region followed by heavily doped Si deposition and chemical mechanical polishing (CMP), as shown in steps 3.1-3. CMP is to planarize the wafer for accurate control of vertical channel length. Then wafer bonding and epitaxy-Si (or SiGe, Ge) growth techniques are used to cover the wafer with Si layers with selective doping in different regions/layers as shown in step 3.4. Consequently, a p/n type Si body is sandwiched by n+/p+ source and drain regions (as shown in step 3.4). After that, N and P active areas with two interconnecting Si on both sides are created with relaxed lithographic requirement (step 3.5, more details will be described later). Then the gate oxide is deposited and metal gate will fill the trenches. Here, gate oxide material can be either SiO2 or high-k dielectric, but only SiO2 is shown in the figure. A following CMP (step 3.6) to polish the materials on top of the column (to avoid wrong interconnect) is performed. Then another oxide is deposited and a subsequent contact opening and connecting steps will follow. The final structure is shown in step 3.7.

Next, an example of process sequence is given in FIG. 4 to describe how to fabricate the structure shown in step 3.4 of FIG. 3. We start from step 3.3 or 4.1 followed by a Si coating with the wafer-bonding technique. Then a heavily doped n+ SiO2 is deposited on top of Si, which provides ion source for drive-in. A thermal annealing is performed such that the ions in the n+ SiO2 region will diffuse into the Si underneath to form n+ Si layer. After this, n+ SiO2 layer can be wet etched away with HF solution. Similar process can be used to form two p+ Si regions as shown in 4.7. In step 4.8, an epitaxy-Si (or SiGe, Ge) layer is grown with very accurate control of the growth rate. Similarly, we can selectively dope the different regions of the epitaxt-Si layer as shown in 4.9. Finally, another heavily doped Si layer can be deposited on top of the epitaxy-Si layer and be doped with different types of dopants.

In FIGS. 5 and 6, we show two examples of process flow to fabricate the structure shown in step 3.5. The process described in FIG. 5 uses the spacer and sacrificial Ge techniques, thus relaxes the lithographic resolution requirement. The process described in FIG. 6 is easier, but it does not provide any lithographic advantage.

### REFERENCES

[1]International Technology Roadmap for Semiconductors (ITRS), 2004 version.
[2] X. Huang et al., “Sub 50-nm FinFET: PMOS,” IEDM Technical Digest, pp. 67-70, 1999.

1. Yijian Chen claims that he invents the vertical integrated-gate CMOS device as shown in the FIG. 2 of the attached document, and he designs several examples of process sequence as shown in FIGS. 3, 4, 5 and 6 of the attached document to fabricate this device.

1. Yijian Chen claims that he invents the vertical integrated-gate CMOS device as shown in the FIG. 2 of the attached document, and he designs several examples of process sequence as shown in FIGS. 3, 4, 5 and 6 of the attached document to fabricate this device.
